(19) United States
(12) Patent Application Publication
(10) Pub. No.: US 2025/0261439 A1
(43) Pub. Date: Aug. 14, 2025

(54) VERTICAL SEMICONDUCTOR DEVICE

(71) Applicant: DENSO CORPORATION, Kariya-city (JP)

(72) Inventors: Takeshi HAGINO, Kariya-city (JP); Kenta GODA, Kariya-city (JP)

(21) Appl. No.: 19/192,895

(22) Filed: Apr. 29, 2025

Related U.S. Application Data
(63) Continuation-in-part of application No. PCT/JP2023/039460, filed on Nov. 1, 2023.

(30) Foreign Application Priority Data
Nov. 2, 2022 (JP) 2022-176618

(51) Int. Cl. H10D 84/00; H10D 30/66; H10D 62/10; H10D 62/60

(52) U.S. Cl. CPC H10D 84/141; H10D 30/665; H10D 30/668; H10D 62/102; H10D 62/60; H10D 62/127

(57) ABSTRACT

A vertical semiconductor device includes a semiconductor substrate having a cell region in which a semiconductor element is disposed, and an outer peripheral region surrounding the cell region. The cell region includes a drift layer of a first conductivity type, a base layer of a second conductivity type, an impurity layer of the first conductivity type, the trench gate structure, a high concentration layer of the first or second conductivity type, an interlayer insulating film, a first electrode and a second electrode. The trench gate structure and the base layer extend from the cell region into the outer peripheral region. A contact hole of the interlayer insulating film extends from the cell region into the outer peripheral region, and the first electrode is connected to the base layer through the contact hole also in the outer peripheral region.

### CROSS REFERENCE TO RELATED APPLICATIONS

The present application is a continuation-in-part application of International Patent Application No. PCT/JP2023/039460 filed on Nov. 1, 2023, which designated the U.S. and claims the benefit of priority from Japanese Patent Application No. 2022-176618 filed on Nov. 2, 2022. The entire disclosures of all of the above applications are incorporated herein by reference.

### TECHNICAL FIELD

The present disclosure relates to a vertical semiconductor device having a trench gate structure.

### BACKGROUND

Conventionally, vertical semiconductor devices having a trench gate structure have been proposed. For example, the vertical semiconductor device is formed with a metal oxide semiconductor field effect transistor (MOSFET) element. More specifically, in the vertical semiconductor device, an n⁻ type drift layer is disposed on an n⁺ type drain region, and a p type base layer is disposed on the drift layer. An n⁺ type source layer is disposed in a surface layer portion of the base layer. A trench gate structure is disposed to penetrate the source layer and the base layer and reach the drift layer.

### SUMMARY

The present disclosure describes a vertical semiconductor device having a semiconductor element with a trench gate structure. According to an aspect, the vertical semiconductor device includes a semiconductor substrate having a cell region in which the semiconductor element is disposed, and an outer peripheral region surrounding the cell region. The cell region may include a drift layer of a first conductivity type, a base layer of a second conductivity type, an impurity layer of the first conductivity type, the trench gate structure, a high concentration layer of the first conductivity type or the second conductivity type, an interlayer insulating film, a first electrode and a second electrode. The trench gate structure and the base layer may extend from the cell region into the outer peripheral region. A contact hole of the interlayer insulating film may extend from the cell region into the outer peripheral region, and the first electrode may be connected to the base layer through the contact hole also in the outer peripheral region.

### BRIEF DESCRIPTION OF THE DRAWINGS

Features and advantages of the present disclosure will become more apparent from the following detailed description made with reference to the accompanying drawings, in which:

FIG. 1 is a plan view of a vertical semiconductor device according to a first embodiment of the present disclosure;

FIG. 2 is a cross-sectional view of the semiconductor device taken along a line II-II in FIG. 1;

FIG. 3 is a cross-sectional view of the semiconductor device taken along a line III-III in FIG. 1;

FIG. 4 is a schematic diagram showing a circuit configuration of the vertical semiconductor device shown in FIG. 1;

FIG. 5 is a diagram showing the relationship between an adjustment distance and an avalanche capability; and

FIG. 6 is a cross-sectional view of a vertical semiconductor device according to a second embodiment of the present disclosure.

### DETAILED DESCRIPTION

To begin with, a relevant technology will be described only for understanding embodiments of the present disclosure.

For example, it has been known a vertical semiconductor device having a trench gate structure. The vertical semiconductor device is formed with an element such as a metal oxide semiconductor field effect transistor (MOSFET). The vertical semiconductor device generally has a cell region in which the MOSFET element is formed, and an outer peripheral region surrounding the cell region. The trench gate structure may be disposed to extend from the cell region to the outer peripheral region so as to alleviate an electric field in the outer peripheral region.

However, in such a vertical semiconductor device, a parasitic bipolar transistor may be formed by a drift layer, a base layer, and a source layer. According to the studying of the inventors of the present disclosure, it has been confirmed that when the trench gate structure is extended to the outer peripheral region, the parasitic bipolar transistor is likely to operate around the trench gate structure disposed in the outer peripheral region. For this reason, it is desirable to enhance an avalanche capability so that the parasitic bipolar transistor is less likely to operate.

The present disclosure provides a vertical semiconductor device capable of improving the avalanche capability.

According to an aspect of the present disclosure, a vertical semiconductor device has a semiconductor element with a trench gate structure. The vertical semiconductor device includes a semiconductor substrate having a cell region in which the semiconductor element is disposed, and an outer peripheral region surrounding the cell region. The cell region includes: a drift layer of a first conductivity type; a base layer of a second conductivity type disposed on the drift layer; an impurity layer of the first conductivity type disposed in a surface layer portion of the base layer and having an impurity concentration higher than that of the drift layer; the trench gate structure including a gate electrode disposed in a trench through a gate insulating film, the trench penetrating the impurity layer and the base layer to reach the drift layer, the trench extending in an extension direction along a planar direction of the semiconductor substrate; a high concentration layer of the first conductivity type or the second conductivity type disposed opposite to the base layer with respect to the drift layer, the high concentration layer having an impurity concentration higher than that of the drift layer; an interlayer insulating film disposed above a surface of the semiconductor substrate and formed with a contact hole to expose the base layer and the impurity layer; a first electrode electrically connected to the impurity layer and the base layer through the contact hole; and a second electrode electrically connected to the high concentration layer. A region of the semiconductor substrate having the impurity layer is defined as the cell region. The trench gate structure extends from the cell region into the outer peripheral region. The base layer extends from the cell region into the outer peripheral region. The contact hole extends from the cell region into the outer peripheral region. The first electrode is connected to the base layer through the contact hole also in the outer peripheral region.

In such a configuration, when the vertical semiconductor device undergoes an avalanche operation, carriers (for example, holes) are easily drawn from the first electrode through the base layer in the outer peripheral region. Therefore, the avalanche capability is enhanced, and it is possible to suppress the parasitic bipolar transistor from operating.

Embodiments of the present disclosure will be hereinafter described with reference to the drawings. In the following descriptions, the same or equivalent parts are denoted by the same reference numerals throughout the embodiments.

### First Embodiment

The following describes a first embodiment with reference to the drawings. For example, a vertical semiconductor device of the present embodiment is preferably mounted on a vehicle such as an automobile and used as a device for driving various electronic devices for the vehicle.

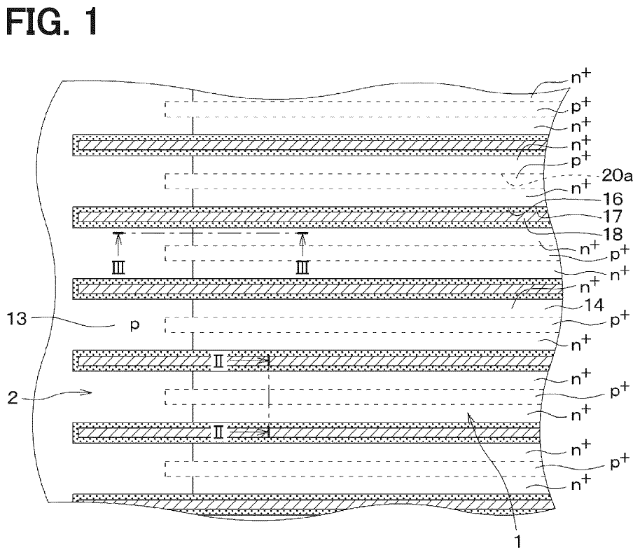

The vertical semiconductor device of the present embodiment has a cell region 1 and an outer peripheral region 2, as shown in FIG. 1. As will be described later in detail, the vertical semiconductor device of the present embodiment is provided with an n-channel type MOSFET element having a source layer 14 as a semiconductor element. In the present embodiment, the cell region 1 and the outer peripheral region 2 are separated depending on whether or not a source layer 14 is formed, and a region in which the source layer 14 is formed is defined as the cell region 1. In other words, a region that actually functions as the MOSFET element corresponds to the cell region 1, and a region that does not function as the MOSFET element corresponds to the outer peripheral region 2. In FIG. 1, illustration of an interlayer insulating film 20 and an upper electrode 21, which will be described later, are omitted. Although FIG. 1 is not a cross-sectional view, a gate insulating film 17 and a gate electrode 18, which will be described later, are hatched to facilitate understanding.

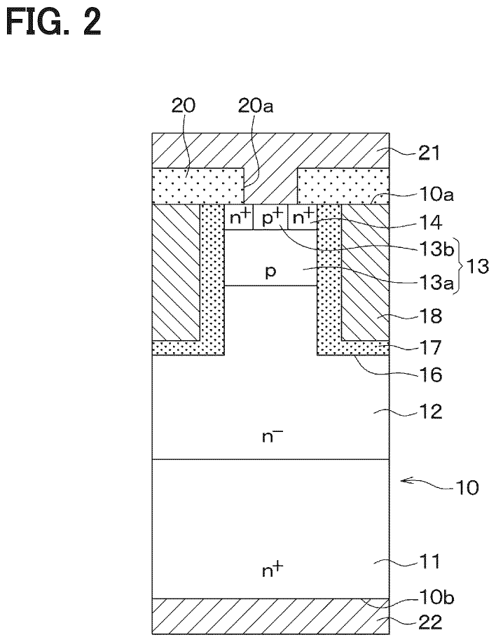

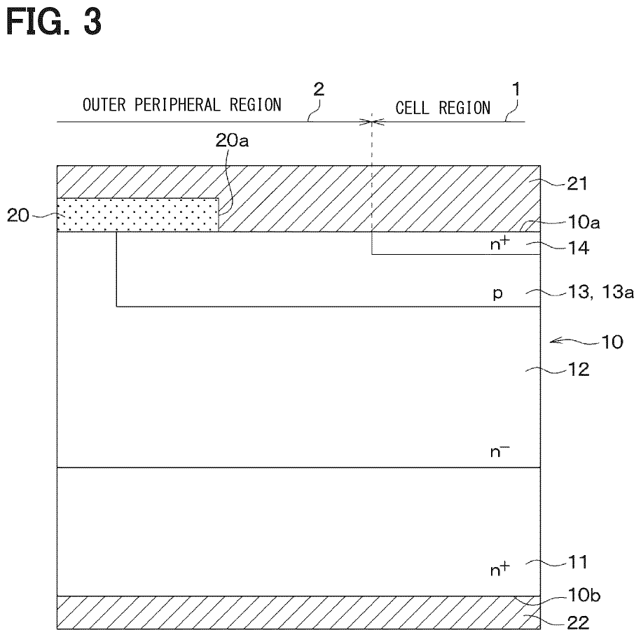

As shown in FIGS. 2 and 3, the vertical semiconductor device of the present embodiment is composed of a semiconductor substrate 10 having a substrate 11. For example, the substrate 11 is made of an n⁺ type silicon substrate or the like having a high impurity concentration. An n⁻ type drift layer 12 having an impurity concentration lower than that of the semiconductor substrate 11 is disposed on the surface of the substrate 11. In the present embodiment, the substrate 11 functions as a drain region and corresponds to a high concentration layer.

A p type base layer 13 having a relatively low impurity concentration is disposed in a surface layer portion of the drift layer 12. The base layer 13 is formed, for example, by ion-implanting a p type impurity into the drift layer 12. The base layer 13 functions as a channel layer that forms a channel region therein. In the present embodiment, the base layer 13 includes a base region 13a located adjacent to the drift layer 12, and a base contact region 13b located above the base region 13a. The base contact region 13b has a higher impurity concentration than the base region 13a. In the present embodiment, the base layer 13 is formed to extend over the cell region 1 and the outer peripheral region 2.

In addition, an n⁺ type source layer 14 is disposed in a surface layer portion of the base layer 13. The source layer 14 has a higher impurity concentration than the drift layer 12. The source layer 14 is formed in an area between the trenches 16 and is in contact with a side surface of the corresponding trench 16. The base contact region 13b is located opposite to the trench 16, which will be described later, with respect to the source layer 14. That is, the source layer 14 is located between the base contact region 13b and the trench 16.

In the present embodiment, the region of the semiconductor substrate 10 having the source layers 14 is defined as the cell region 1. The base contact region 13b may be disposed so as to coincide with the source layer 14 in a longitudinal direction (i.e., an extension direction) of the trench 16 described later, or may be disposed so as to protrude slightly from the cell region 1 into the outer peripheral region 2. In the present embodiment, the source layer 14 corresponds to an impurity layer. The semiconductor substrate 10 has a first surface 10a on a side adjacent to the base layer 13 and the source layer 14, and a second surface 10b on a side adjacent to the substrate 11.

The semiconductor substrate 10 is formed with multiple trenches 16. Each of the trenches 16 is formed in the semiconductor substrate 10 so as to penetrate the base layer 13 and the source layer 14 from the first surface 10a and to reach the drift layer 12. Each of the trenches 16 is disposed to have a longitudinal direction in one direction along a planar direction of the semiconductor substrate 10. The multiple trenches 16 are arranged in a direction intersecting the one direction. More specifically, the multiple trenches 16 are arranged in parallel at equal intervals to form a striped layout. In FIG. 1, the trenches 16 extend in a left and right direction of a paper plane of FIG. 1 as the longitudinal direction and are arranged in an up and down direction of the paper plane of FIG. 1. The planar direction of the semiconductor substrate 10 corresponds to a direction substantially parallel to the first surface 10a. Each trench 16 is disposed such that both ends in the longitudinal direction protrude from the cell region 1 into the outer peripheral region 2.

An inner wall surface of the trench 16 is covered with a gate insulating film 17. A gate electrode 18 is disposed in the trench 16 through the gate insulating film 17. The gate electrode 18 is made of doped polysilicon.

An interlayer insulating film 20 is disposed above the first surface 10a of the semiconductor substrate 10 so as to cover the gate electrode 18. The interlayer insulating film 20 is made of, for example, an oxide film. The interlayer insulating film 20 is formed with a contact hole 20a to expose the source layer 14 and the base layer 13.

In the present embodiment, the contact hole 20a is formed so as to extend beyond the source layer 14 in the longitudinal direction of the trench 16. In other words, the contact hole 20a is formed so as to expose the base layer 13 located in the outer peripheral region 2 as well. However, the contact hole 20a is formed so as to terminate at a position closer to the cell region 1 than the end of the trench 16 in the longitudinal direction. In FIG. 1, the contact hole 20a is indicated by a dotted line. That is, in FIG. 1, a region surrounded by the dotted line is a region exposed from the interlayer insulating film 20.

An upper electrode 21, which corresponds to a source electrode, is disposed above the interlayer insulating film 20. Specifically, in the cell region 1, the upper electrode 21 is disposed so as to be connected to the source layer 14 and the base contact region 13b (that is, the base layer 13) through the contact hole 20a. Moreover, in the outer peripheral region 2, the upper electrode 21 is disposed so as to be connected to the base layer 13 through the contact hole 20a. In the present embodiment, the upper electrode 21 corresponds to a first electrode.

A lower electrode 22, which corresponds to a drain electrode, is formed adjacent to the second surface 10b of the substrate 11. In the present embodiment, the lower electrode 22 corresponds to a second electrode.

The vertical semiconductor device according to the present embodiment has the configuration as described above. In the present embodiment, the n⁻ type, the n type, and the n⁺ type correspond to a first conductivity type, and the p type and the p⁺ type correspond to a second conductivity type. In the present embodiment, as described above, the semiconductor substrate 10 is configured to include the substrate 11, the drift layer 12, the base layer 13, the source layer 14, and the like.

Next, operations and effects of the vertical semiconductor device will be described. First, in the vertical semiconductor device as described above, when a voltage equal to or higher than a threshold voltage of an insulated gate structure is applied to the gate electrode 18, a channel region is formed in a portion of the base layer 13 that contacts the trench 16, and a current occurs between the source and the drain, so that the vertical semiconductor device is turned on. When the voltage applied to the gate electrode 18 becomes less than the threshold voltage, the channel region formed in the base layer 13 disappears, and the current is cut off. As a result, the vertical semiconductor device is turned off.

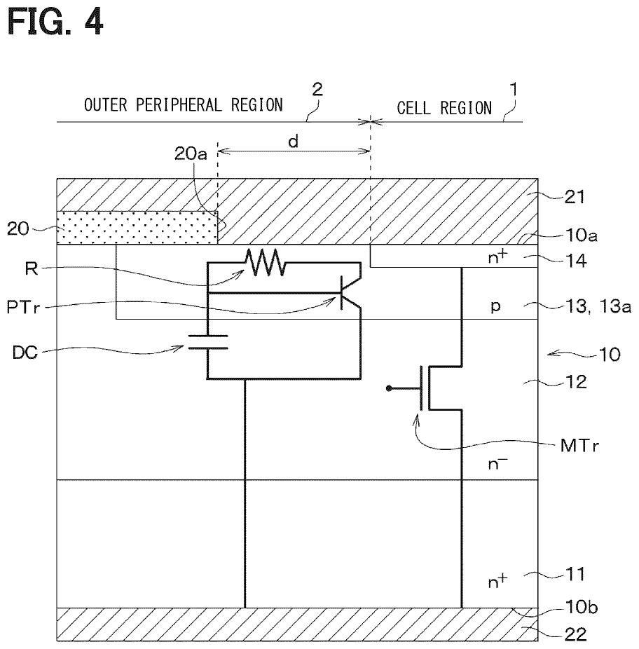

The vertical semiconductor device described above has a circuit configuration as shown in FIG. 4. That is, the vertical semiconductor device of the present embodiment has a circuit configuration including a MOS transistor MTr, a parasitic bipolar transistor PTr formed by the drift layer 12, the base layer 13 and the source layer 14, a depletion capacitor DC, and an internal resistance R of the base layer 13. When the vertical semiconductor device described above is switched from an on state to an off state, avalanche breakdown may occur, causing an excessive current to flow between the source and the drain.

Therefore, in the present embodiment, the contact hole 20a is extended to the outer peripheral region 2 so that the base layer 13 is electrically connected to the upper electrode 21 in the outer peripheral region 2. As a result, when the vertical semiconductor device undergoes an avalanche operation, holes are easily drawn from the upper electrode 21 through the base layer 13 in the outer peripheral region 2. In other words, a region in which the internal resistance R of the base layer 13 is small increases. For this reason, an avalanche capability can be enhanced, and it is possible to restrict the parasitic bipolar transistor PTr from operating.

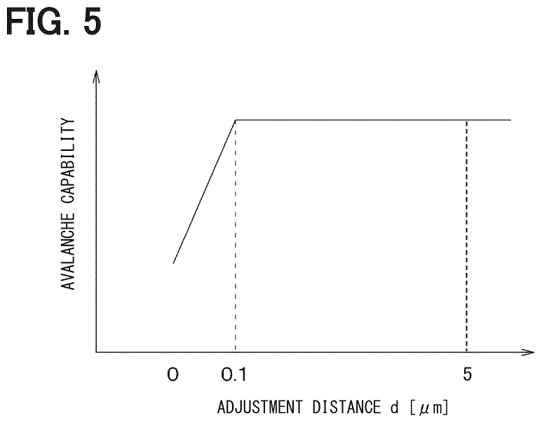

As shown in FIG. 4, the length of the contact hole 20a protruding from the cell region 1 into the outer peripheral region 2 is referred to as an adjustment distance d. That is, the length of the contact hole 20a protruding from the source layer 14 in the outer peripheral region 2 is referred to as the adjustment distance d. In other words, the length of the portion of the base layer 13 that is connected to the upper electrode 21 in the outer peripheral region 2 along the longitudinal direction of the trench 16 is referred to as the adjustment distance d. In this case, the longer the adjustment distance d is, the easier the holes are drawn from the upper electrode 21. However, according to the study by the inventors of the present disclosure, it has been confirmed that the avalanche capability remains almost unchanged when the adjustment distance d is 0.1 micrometers (μm) or more, as shown in FIG. 5. In the present embodiment, therefore, the adjustment distance d is set to 0.1 μm or more.

Note that FIG. 5 shows the results in which the impurity concentration of the substrate 11 is 1×10¹⁸ to 1×10²⁰ cm⁻³, the impurity concentration of the drift layer 12 is 1×10¹⁶ to 1×10¹⁸ cm⁻³, the impurity concentration of the base region 13a is 1×10¹³ cm⁻³, the impurity concentration of the base contact region 13b is about 1×10¹⁵ to 1×10¹⁶ cm⁻³, and the impurity concentration of the source layer 14 is about 1×10¹³ cm⁻³.

As described above, in the present embodiment, the contact hole 20a is extended from the cell region 1 into the outer peripheral region 2, and the upper electrode 21 is connected to the base layer 13 also in the outer peripheral region 2. Therefore, when the vertical semiconductor device undergoes an avalanche operation, holes are easily drawn from the upper electrode 21 through the base layer 13 in the outer peripheral region 2. As such, the avalanche capability can be enhanced, and it is possible to restrict the parasitic bipolar transistor PTr from operating.
(1) In the present embodiment, the adjustment distance d is set to 0.1 μm or more. Therefore, it is possible to sufficiently enhance the avalanche capability.
(2) In addition, the adjustment distance d may be less than 5 μm. In a case where the adjustment distance d is equal to or more than 0.1 μm and less than 5 μm, the avalanche capability can be enhanced as well as an increase in size of the vertical semiconductor device can be suppressed. In other words, even if the adjustment distance d of the contact hole 20a is such a short distance of less than 5 μm but 0.1 μm or more, it is possible to enhance the avalanche capability.

### Second Embodiment

The following describes a second embodiment. The present embodiment is provided with a trench contact, in comparison with the vertical semiconductor device of the first embodiment. The other configurations of the present embodiment are similar to those of the first embodiment, and therefore a description of the similar configurations will not be repeated.

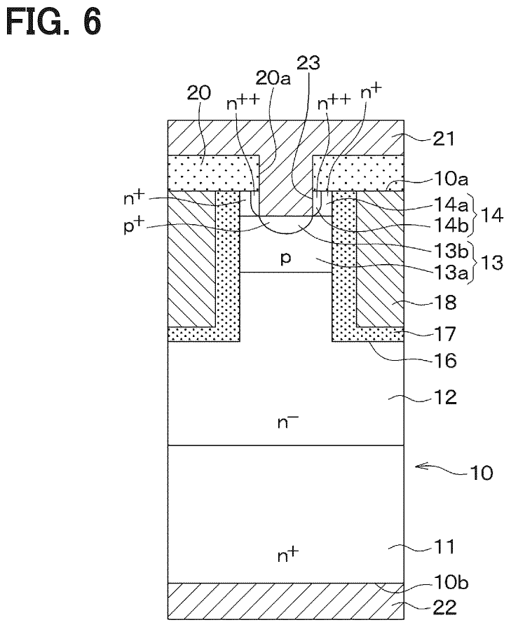

In the present embodiment, as shown in FIG. 6, a contact trench 23 is formed in the semiconductor substrate 10 so as to communicate with the contact hole 20a formed in the interlayer insulating film 20. More specifically, the contact trench 23 is formed so as to coincide with the contact hole 20a in the normal direction to the first surface 10a of the semiconductor substrate 10. That is, similar to the contact hole 20a, the contact trench 23 has the adjustment distance d from the cell region 1 of 0.1 μm or more. Also in this case, the adjustment distance d of the contact trench 23 may be less than 5 μm, similar to the first embodiment.

In the present embodiment, the source layer 14 includes a source region 14a located adjacent to the gate insulating film 17, and a source contact region 14b contacting a side surface of the contact trench 23. The source contact region 14b has a higher impurity concentration than the source region 14a. In other words, the source contact region 14b defines the side surface of the contact trench 23. In addition, the base contact region 13b is formed so as to be in contact with the bottom surface of the contact trench 23. In other words, the base contact region 13b defines the bottom surface of the contact trench 23.

According to the present embodiment described above, the contact hole 20a is extended from the cell region 1 to the outer peripheral region 2, and the upper electrode 21 is connected to the base layer 13 also in the outer peripheral region 2. Therefore, effects similar to those of the first embodiment can be achieved.

For example, it is also conceivable to have a configuration in which the contact hole 20a and the contact trench 23 are not extended into the outer peripheral region 2, but another contact hole is formed in the outer peripheral region 2 to connect the upper electrode 21 to the base layer 13 in the outer peripheral region 2. In such a configuration, however, it is necessary to perform the process of forming the contact trench 23 and the contact hole 20a and the process of forming another contact hole separately, increasing the number of manufacturing processes. On the other hand, in the vertical semiconductor device of the present embodiment, it is possible to achieve the similar effects to those of the first embodiment while suppressing an increase in the number of manufacturing processes.
(1) In the present embodiment, the contact trench 23 is formed in the semiconductor substrate 10, and the source contact region 14b and the base contact region 13b are formed to be in contact with the contact trench 23, that is, adjacent to the contact trench 23. Therefore, it is possible to ensure the contact area with the upper electrode 21 easily and shorten the distance between adjacent trenches 16. As such, it is possible to reduce the on-resistance and to make the vertical semiconductor device smaller.

### Other Embodiments

Although the present disclosure has been described in accordance with the embodiments, it is understood that the present disclosure is not limited to the embodiments described or the structures thereof. The present disclosure includes various modification examples and modifications within the equivalent scope. In addition to the various combinations and configurations, which are preferred, other combinations and configurations, including more, less, or only a single element, are also within the spirit and scope of the present disclosure.

For example, in each of the embodiments described above, the n-channel type trench gate MOSFET in which the first conductivity type is the n type and the second conductivity type is the p type has been illustrated. However, the vertical semiconductor device may be configured to have a p-channel type trench gate MOSFET in which the conductivity type of each component is inverted with respect to the n-channel type. For example, the vertical semiconductor device may be configured to have an element other than the MOSFET, such as an insulated gate bipolar transistor (IGBT) having a similar structure to the MOSFET. In the case of the IGBT, the n⁺ type substrate 11 in each of the embodiments is modified to the p⁺ type collector layer, and the other configurations of the IGBT is similar to those of the MOSFET as described in each of the embodiments.

In each of the embodiments described above, the semiconductor substrate 10 has been illustrated as a silicon substrate. However, the semiconductor substrate 10 may be a silicon carbide substrate or a gallium nitride substrate.

In each of the embodiments described above, the base contact region 13b may not be formed, and the base layer 13 may be directly connected to the upper electrode 21. In the first embodiment, the source contact region 14b may be formed so as to be connected to the upper electrode 21. In the second embodiment, the source contact region 14b may not be formed.

What is claimed is:

1. A vertical semiconductor device having a semiconductor element with a trench gate structure, the vertical semiconductor device comprising:
a semiconductor substrate having a cell region in which the semiconductor element is disposed, and an outer peripheral region surrounding the cell region, wherein
the cell region includes:
a drift layer of a first conductivity type;
a base layer of a second conductivity type disposed on the drift layer;
an impurity layer of the first conductivity type disposed in a surface layer portion of the base layer and having an impurity concentration higher than that of the drift layer;
the trench gate structure including a gate electrode disposed in a trench through a gate insulating film, the trench penetrating the impurity layer and the base layer to reach the drift layer, the trench extending in an extension direction along a planar direction of the semiconductor substrate;
a high concentration layer of the first conductivity type or the second conductivity type disposed opposite to the base layer with respect to the drift layer, the high concentration layer having an impurity concentration higher than that of the drift layer;
an interlayer insulating film disposed above a surface of the semiconductor substrate and formed with a contact hole to expose the base layer and the impurity layer;
a first electrode electrically connected to the impurity layer and the base layer through the contact hole; and
a second electrode electrically connected to the high concentration layer, wherein
a region of the semiconductor substrate having the impurity layer is defined as the cell region,
the trench gate structure extends from the cell region into the outer peripheral region,
the base layer extends from the cell region into the outer peripheral region,
the contact hole extends from the cell region into the outer peripheral region,
the first electrode is connected to the base layer through the contact hole also in the outer peripheral region,
the contact hole has, as an adjustment distance, a length in the extension direction of the trench in the outer peripheral region, and
the adjustment distance is equal to or more than 0.1 μm and less than 5 μm.

2. The vertical semiconductor device according to claim 1, wherein
the semiconductor substrate is formed with a contact trench that is communicated with the contact hole,
the impurity layer is disposed in contact with a side surface of the contact trench, and
the base layer is disposed in contact with a bottom surface of the contact trench.
